(19) United States
(12) Patent Application Publication
(10) Pub. No.: US 2024/0068068 A1
(43) Pub. Date: Feb. 29, 2024

(54) SUBSTRATE PROCESSING DEVICE, SUBSTRATE PROCESSING SYSTEM, AND METHOD FOR PROCESSING SUBSTRATE

(71) Applicant: ULVAC, INC., Chigasaki-shi (JP)

(72) Inventors: Kazuhiro Sonoda, Chigasaki-shi (JP); Daisuke Mori, Chigasaki-shi (JP); Masashi Okada, Chigasaki-shi (JP)

(21) Appl. No.: 18/457,109

(22) Filed: Aug. 28, 2023

(30) Foreign Application Priority Data
Aug. 30, 2022 (JP) 2022-136421

(51) Int. Cl. C22B 5/18

(52) U.S. Cl. CPC C22B 5/18

(57) ABSTRACT

A substrate processing device reduces a surface of a substrate. The surface includes a metal layer. The substrate processing device includes a chamber body, a hot plate, a plasma supply unit, and a controller. The hot plate is accommodated in the chamber body and configured to set the substrate. The plasma supply unit is configured to supply plasma of a hydrogen gas to the chamber body. The controller is configured to execute a degassing process and a reducing process. In the degassing process, the controller drives the hot plate to remove an adsorbate from the surface before driving the plasma supply unit. In the reducing process, the controller drives the plasma supply unit after driving the hot plate to supply the plasma to the surface that has undergone the degassing process.

### CROSS REFERENCE TO RELATED APPLICATION

This application claims priority to and incorporates by reference Japanese patent application no. 2022-136421 filed 30 Aug. 2022.

### TECHNICAL FIELD

The following description relates to a substrate processing device, a substrate processing system, and a method for processing a substrate that reduce a surface of a metal layer.

### BACKGROUND

Hydrogen ions and hydrogen radicals included in the plasma of a hydrogen gas reduce an oxide formed on a surface of a metal layer. In an example of a substrate processing device, the hydrogen gas is mixed with an additive gas. An additive gas including nitrogen atoms or oxygen atoms avoids deactivation of active species generated from the hydrogen gas (as discussed in International Patent Publication No. 2017/029961).

### SUMMARY

An adsorbate in the surface of the metal layer hinders reduction of the oxide formed on the surface of the metal layer. For example, an adsorbate is adsorbed in the surface of a metal layer inside an apparatus for forming a metal layer or adsorbed in the metal layer when a substrate is transferred from the apparatus for forming a metal layer to an apparatus for reducing oxides. In order to improve the performance and the yield of a device including the metal layer, it is desirable that oxide residue, which results from the adsorbate, be sufficiently reduced.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a substrate processing device reduces a surface of a substrate. The surface includes a metal layer. The substrate processing device includes a chamber body, a hot plate, a plasma supply unit, and a controller. The hot plate is accommodated in the chamber body and configured to set the substrate. The plasma supply unit is configured to supply plasma of a hydrogen gas to the chamber body. The controller is configured to execute a degassing process and a reducing process. In the degassing process, the controller drives the hot plate to remove an adsorbate from the surface before driving the plasma supply unit. In the reducing process, the controller drives the plasma supply unit, after driving the hot plate, to supply the plasma to the surface that has undergone the degassing process.

In another general aspect, a substrate processing system reduces a surface of a substrate. The surface includes a metal layer. The system includes the above substrate processing device and a film forming chamber connected to the chamber body via a transfer chamber. The metal layer is a first metal layer, and the film forming chamber is configured to form a second metal layer on the surface after the reducing process.

In another general aspect, a method for processing a substrate reduces a surface of the substrate. The surface includes a metal layer. The method includes a degassing process for supplying a heat conductive gas to a chamber body, after setting the substrate on a hot plate accommodated in the chamber body, to increase a pressure of the chamber body and heating the hot plate to remove an adsorbate from the surface. The method further includes a reducing process performed after discharging the heat conductive gas from the chamber body. The reducing process is performed by supplying plasma of a hydrogen gas to the surface of the substrate set on the hot plate that has undergone the degassing process.

The substrate processing device, the substrate processing system, and the method for processing a substrate according to the present disclosure minimize insufficient reduction of the surface of the metal layer.

Other features and aspects will be apparent from the following detailed description, the drawings, and the claims.

### BRIEF DESCRIPTION OF THE DRAWINGS

FIG. 1 is a diagram showing the configuration of a substrate processing system.

FIG. 2 is a diagram showing the structure of a substrate processing device included in the substrate processing system.

FIG. 3 is a flowchart illustrating a process sequence of a method for processing a substrate.

FIG. 4 is a timing chart illustrating a gas supply sequence of the method for processing a substrate.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Substrate Processing System

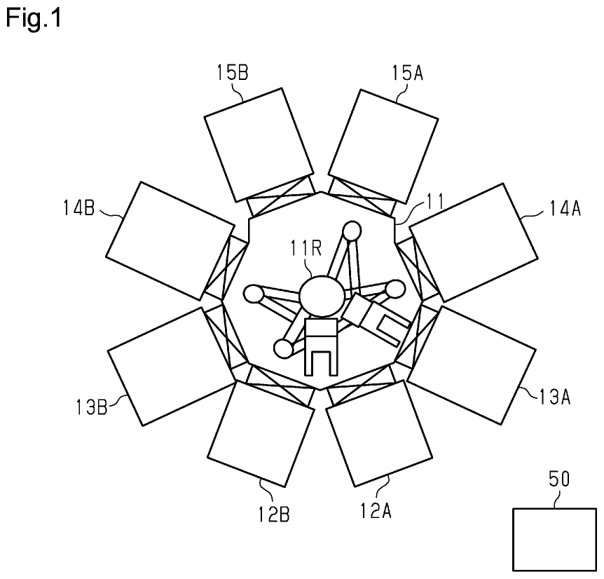

As shown in FIG. 1, a substrate processing system includes a transfer chamber 11, two loading/unloading chambers 12A and 12B, two film forming chambers 13A and 13B, two pre-processing chambers 14A and 14B, two cooling chambers 15A and 15B, and a controller 50. The substrate processing system shown in FIG. 1 includes a single transfer chamber 11. However, the substrate processing system may include multiple transfer chambers 11.

A substrate S is loaded and unloaded in the loading/unloading chamber 12A, 12B. The substrate S is the subject supplied with the plasma of a hydrogen gas FH2 (refer to FIG. 4). The substrate S includes a first metal layer formed from copper, tungsten, or the like on a surface of the substrate S. The surface of the first metal layer includes an oxide of the metal forming the first metal layer. The surface of the substrate S may include a silicon layer or a silicon oxide layer.

The surface of the substrate S is pre-processed in the pre-processing chamber 14A, 14B. The pre-process includes a degassing process using a heat conductive gas FHE (refer to FIG. 4) and a reducing process using the plasma of the hydrogen gas FH2. A film forming process is performed on the surface of the substrates S in the film forming chamber 13A, 13B. A second metal layer is formed on the pre-processed substrate S in the film forming chamber 13A, 13B. The substrate S that has undergone the film forming process is cooled in the cooling chamber 15A, 15B.

Hereafter, a substrate processing device, the substrate processing system, and a method for processing a substrate will be described with the loading/unloading chamber 12A, the film forming chamber 13A, the pre-processing chamber 14A, and the cooling chamber 15A. Descriptions of the loading/unloading chamber 12B, the film forming chamber 13B, the pre-processing chamber 14B, and the cooling chamber 15B overlap those of the loading/unloading chamber 12A, the film forming chamber 13A, the pre-processing chamber 14A, and the cooling chamber 15A. Thus, such descriptions will be omitted.

A substrate S having the metal layer is loaded into the substrate processing system in the loading/unloading chamber 12A. The processed substrate S is unloaded from the substrate processing system in the loading/unloading chamber 12A.

The transfer chamber 11 is connected to each of the chambers 12A, 12B, 13A, 13B, 14A, 14B, 15A and 15B. The transfer chamber 11 includes a transfer robot 11R. The transfer robot 11R transfers the substrate S in accordance with an instruction from the controller 50. The transfer robot 11R transfers an unprocessed substrate S from the loading/unloading chamber 12A to the transfer chamber 11. The transfer robot 11R transfers the unprocessed substrate S from the transfer chamber 11 to the pre-processing chamber 14A. The transfer robot 11R transfers the pre-processed substrate S from the pre-processing chamber 14A to the film forming chamber 13A. The transfer robot 11R transfers the substrate S that has undergone the film forming process from the film forming chamber 13A to the cooling chamber 15A. The transfer robot 11R transfers the cooled substrate S from the cooling chamber 15A to the loading/unloading chamber 12A.

The controller 50 includes an electronic circuit such as a central processing unit (CPU), a micro-processing unit (MPU), or the like. The controller 50 includes storage such as a solid state drive (SSD), a hard disk drive (HDD), or the like. The controller 50 includes a memory such as a read-only memory (ROM), a random-access memory (RAM), a registered memory, or the like. The controller 50 may include an integrated circuit such as an application specific integrated circuit (ASIC), a field-programmable gate array (FPGA), or the like. The controller 50 includes a substrate processing program for performing a method for processing a substrate. The controller 50 executes the substrate processing program to have the chambers 12A, 12B, 13A, 13B, 14A, 14B, 15A, and 15B perform a transfer process, a reducing process, a film forming process, and a cooling process on the substrate S. All the processes performed in each chamber may be executed by software included in the controller 50 or a combination of an integrated circuit and software included in the controller 50.

Substrate Processing Device

The substrate processing device includes the pre-processing chamber 14A and the controller 50.

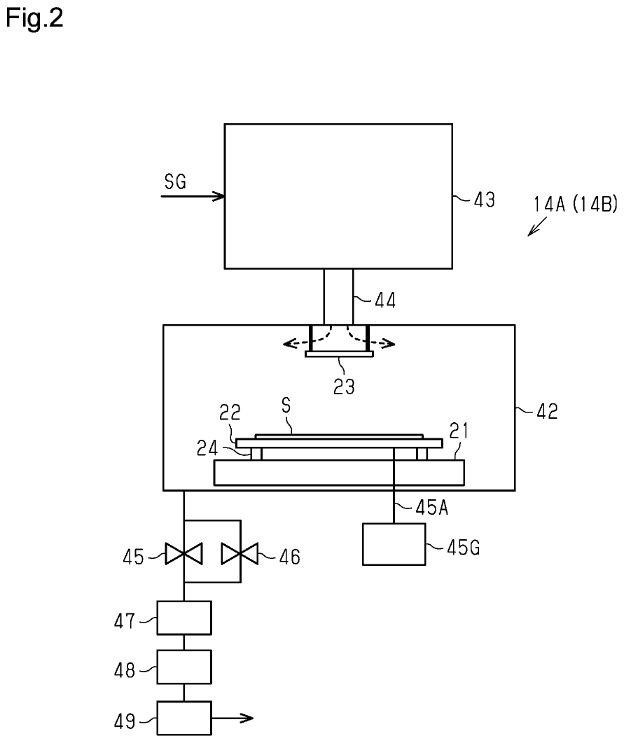

As shown in FIG. 2, the pre-processing chamber 14A includes a chamber body 42 and a plasma generation unit 43. The chamber body 42 is connected to the plasma generation unit 43 by a supply pipe 44.

The plasma generation unit 43 is supplied with various types of process gases SG from various supply pipes. The plasma generation unit 43 is connected to a supply pipe of the hydrogen gas FH2 (refer to FIG. 4), a supply pipe of an additive gas, and a supply pipe of the heat conductive gas FHE (refer to FIG. 4). The additive gas may include at least one selected from the group consisting of nitrogen gas, oxygen gas FO2 (refer to FIG. 4), nitrogen monoxide gas, nitrogen dioxide gas, ammonia, argon gas FAR (refer to FIG. 4), and noble gas. The heat conductive gas FHE includes a noble gas such as helium.

The plasma generation unit 43 generates plasma of the hydrogen gas FH2. The plasma generation unit 43 may be a magnetron plasma source or an inductively coupled plasma source as long as the plasma generation unit 43 generates plasma from the hydrogen gas FH2 or a mixture gas of the hydrogen gas FH2 and the additive gas. The plasma of the hydrogen gas FH2 includes hydrogen-ions and hydrogen-radicals that have the reducing property. The controller 50 controls the plasma generation unit 43 to start and stop the plasma generation. In the reducing process, the controller 50 has the plasma generation unit 43 generate the plasma of the hydrogen gas FH2 and supply the plasma of the hydrogen gas FH2 to the chamber body 42.

The plasma generation unit 43 supplies the heat conductive gas FHE to the chamber body 42 to heat the substrate S. The controller 50 controls the plasma generation unit 43 to start and stop the supply of the heat conductive gas FHE. In the degassing process, the controller 50 has the plasma generation unit 43 supply the heat conductive gas FHE.

The supply pipe 44 is connected to the chamber body 42 and the plasma generation unit 43. The supply pipe 44 delivers the plasma generated by the plasma generation unit 43 toward the chamber body 42. The supply pipe 44 may include an inner surface of the flow passage that is formed from sintered alumina. The supply pipe 44 may be a pipe formed from sintered alumina. The length of the flow passage of the supply pipe 44 is, for example, in a range of 50 mm to 200 mm. The length of the flow passage of the supply pipe 44 is set such that the ions generated by the plasma generation unit 43 reach the chamber body 42 less frequently.

The plasma generation unit 43 and the supply pipe 44 form a plasma supply unit. The plasma generation unit 43 also serves as a heat medium supply unit that supplies the heat conductive gas FHE to the chamber body 42.

The chamber body 42 is connected to a discharge system. The discharge system includes a main valve 45, a bypass valve 46, a cold trap 47, a turbo pump 48, and a discharge pump 49. The cold trap 47, the turbo pump 48, and the discharge pump 49 form a discharge device.

The main valve 45 opens and closes a main pipe. The main pipe connects the chamber body 42 to the cold trap 47. The bypass valve 46 opens and closes a bypass pipe. The bypass pipe also connects the chamber body 42 to the cold trap 47 and bypasses the main pipe. The bypass pipe has a higher flow passage resistance than the main pipe.

In the degassing process, the controller 50 closes the main valve 45 and opens the bypass valve 46. In this manner, the controller 50 forms a high-pressure environment of the chamber body 42 in the degassing process. In the reducing process, the controller 50 opens the main valve 45 and closes the bypass valve 46. In this manner, the controller 50 forms a low-pressure environment of the chamber body 42 in the reducing process.

The chamber body 42 accommodates a support 21, a hot plate 22, and a diffusion member 23. The hot plate 22 is connected to a heating power supply 45G by a power supply line 45A. The power supply line 45A is used for increasing the temperature of the hot plate 22. The electric wire connected to the hot plate 22 is only as the power supply line 45A.

The diffusion member 23 is arranged facing the outlet of the supply pipe 44. The diffusion member 23 may include a surface formed from sintered alumina. The diffusion member 23 may be formed from sintered alumina. The plasma flowing from the outlet of the supply pipe 44 toward the diffusion member 23 strikes the diffusion member 23. This diffuses the plasma of the hydrogen gas FH2 in a radial direction of the chamber body 42. The diffusion of the plasma by the diffusion member 23 facilitates deactivation of short-lived ions and reduction by long-lived radicals.

The support 21 supports the hot plate 22 with a heat insulator 24. The support 21 is connected to ground potential. The support 21 forms a gap between the support 21 and the hot plate 22. The heat insulator 24 is arranged in the gap between the support 21 and the hot plate 22 to support the hot plate 22. The gap between the support 21 and the hot plate 22 avoids short circuiting of the hot plate 22. The substrate S is set on the hot plate 22. The surface of the substrate S includes the first metal layer. The hot plate 22 heats the substrate S set on the hot plate 22 with the current from the heating power supply 45G. The controller 50 controls the heating power supply 45G to start and stop the current supply.

Substrate Processing Method

A method for processing a substrate performed by the substrate processing device will now be described.

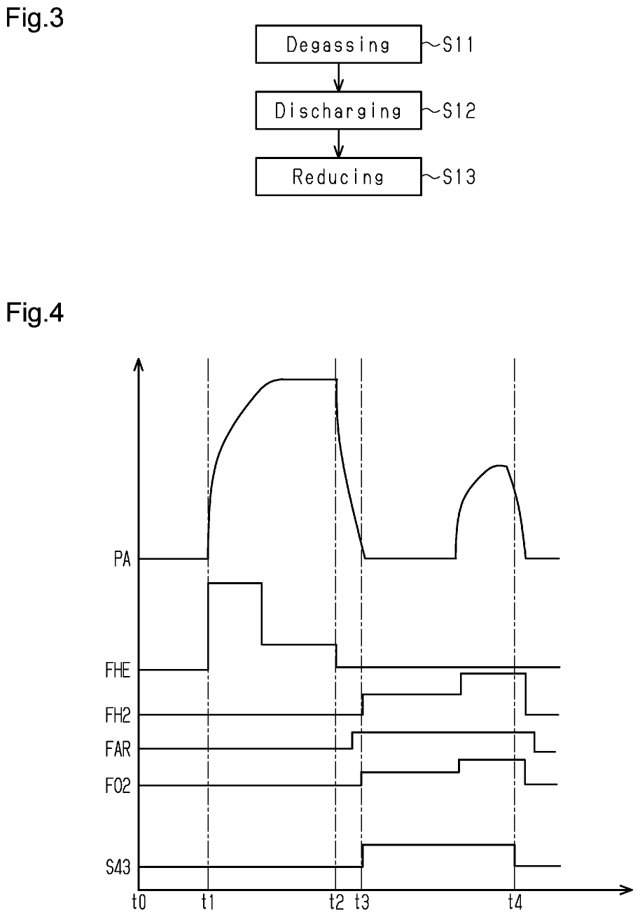

As shown in FIG. 3, the substrate processing method includes the degassing process (step S11), a discharging process (step S12), and the reducing process (step S13). The degassing process removes an adsorbate from the surface of the substrate S. The discharging process discharges the heat conductive gas FHE from the chamber body 42 after the degassing process. The reducing process supplies the plasma of the hydrogen gas FH2 to the substrate S after the discharging process. The substrate processing system forms a second metal layer on the surface of the substrate S in the film forming chamber 13A, 13B after the reducing process.

As shown in FIG. 4, at time to, the controller 50 drives the transfer robot 11R to transfer the substrate S from the loading/unloading chamber 12A to the pre-processing chamber 14A. The controller 50 sets the substrate S on the hot plate 22 and starts driving the hot plate 22. In this manner, the controller 50 starts raising the temperature of the substrate S.

At time t1, the controller 50 starts supplying the heat conductive gas FHE from the plasma generation unit 43 to the chamber body 42. Further, the controller 50 closes the main valve 45 and opens the bypass valve 46. The controller 50 increases a pressure PA of the chamber body 42 to form a high-pressure environment of the chamber body 42 with the heat conductive gas FHE. In this manner, the controller 50 applies pressure to the chamber body 42 in addition to heating the hot plate 22. Thus, adsorbates are more efficiently removed from the surface of the substrate S.

At time t2, the controller 50 stops the supply of the heat conductive gas FHE. Further, the controller 50 opens the main valve 45 and closes the bypass valve 46. Before opening the main valve 45, the controller 50 may evacuate the chamber body 42 with the bypass valve 46 for one to nine seconds such that the pressure of the chamber body 42 is reduced to the maximum allowable intake pressure of the turbo pump 48. Then, the controller 50 begins the discharging process. Further, the controller 50 starts supplying the argon gas FAR, the oxygen gas FO2, and the hydrogen gas FH2 by time t3. The argon gas FAR and the oxygen gas FO2 are additive gases.

After a low-pressure environment of the chamber body 42 is formed with the argon gas FAR, the oxygen gas FO2, and the hydrogen gas FH2, the controller 50 inputs a drive signal S43 to the plasma generation unit 43 to start driving the plasma generation unit 43. Alternatively, only the argon gas FAR having a low ionization voltage may first be introduced to generate plasma, and then the oxygen gas FO2 and the hydrogen gas FH2 may be introduced so as to stabilize plasma ignition. The controller 50 continues supplying the plasma of the hydrogen gas FH2 to the surface of the substrate S until time t4. In this manner, the controller 50 reduces the oxides on the surface of the first metal layer that has undergone the degassing process.

The above embodiment has the following advantages.

(1) The degassing process and the reducing process are performed in the single chamber body 42. This facilitates the reduction of the oxides as compared to a substrate processing device that does not perform the degassing process. Also, the substrate does not have to be transferred between chambers, unlike when the substrate processing device performs the degassing process and the reducing process in separate chambers. Accordingly, the substrate S is processed more efficiently since adsorbing when the substrate S is transferred will be limited. As a result, the oxide residue resulting from adsorbates is minimized. Consequently, insufficient reduction due to the oxide residue is avoided.

(2) The heat conduction gas FHE supplied in the degassing process readily transfers the heat of the hot plate 22 to the surface of the substrate S. This accelerates the temperature rise of the first metal layer, thereby reducing the time required for the degassing process.

(3) The heat conductive gas FHE remains in the chamber body 42 for a longer period of time as compared to when the main pipe is used in the degassing process. This readily transfers the heat of the hot plate 22 to the surface of the substrate S, thereby further reducing the time required for the degassing process.

(4) The gap is formed between the hot plate 22 and the support 21, and the hot plate 22 is connected to the support 21 with the heat insulator 24. Accordingly, the heat of the hot plate 22 will be dissipated only toward the substrate S. This accelerates the temperature rise of the first metal layer, thereby further reducing the time required for the degassing process.

(5) The gap between the hot plate 22 and the support 21 limits heat dissipation of the hot plate 22 toward the support 21. If a gap is formed between the hot plate 22 and the support 21, and the hot plate 22 electrostatically attracts the substrate S, abnormal discharge is likely to occur in the gap between the hot plate 22 and the support 21 due to the power supply required for the electrostatic attraction and the pressure increased by the heat conductive gas FHE during the degassing process. However, the above embodiment does not need a power supply for electrostatic attraction. This avoids an occurrence of abnormal discharge in the gap between the support 21 and the hot plate 22.

(6) The diffusion of the plasma by the diffusion member 23 facilitates deactivation of short-lived ions and reduction by long-lived radicals. This avoids a situation in which the substrate S is damaged by an excessive supply of ions. However, the diffusion of the plasma by the diffusion member 23 involves an extensive history of thermal exposure of the diffusion member 23 over time. The extensive thermal history of the diffusion member 23 leads to an increase in particles resulting from displacement of the diffusion member 23. In this respect, the supply pipe 44 arranged between the plasma generation unit 43 and the diffusion member 23 increases the flow passage length of the plasma so that a smaller number of ions reaches the diffusion member 23. Therefore, the diffusion of the plasma by the diffusion member 23 and the extension of the flow passage by the supply pipe 44 avoid both damage to the substrate S and increases the particles.

### Modified Examples

The above embodiment may be modified as follows.

The surface of the diffusion member 23 may be covered with an anodic oxide film. The inner surface of the supply pipe 44 may be covered with an anodic oxide film.

The hot plate 22 may be an electrostatic chuck that electrostatically attracts the substrate S. In this case, the controller 50 lowers the pressure of the chamber body 42 in the degassing process and the reducing process to avoid an occurrence of abnormal discharge in the gap between the support 21 and the hot plate 22.

The substrate processing device may include a single exhaust pipe that is used in the degassing process and the reducing process. In other words, the substrate processing device may perform the degassing process using the main pipe.

The substrate processing device may include a heat medium supply unit differing from the plasma generation unit 43 and supply the heat conductive gas FHE from the heat medium supply unit to the chamber body 42.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A substrate processing device to reduce a surface of a substrate, the surface including a metal layer, the substrate processing device comprising:
a chamber body;
a hot plate accommodated in the chamber body and configured to set the substrate;
a plasma supply unit configured to supply plasma of a hydrogen gas to the chamber body; and
a controller configured to execute:
a degassing process by driving the hot plate to remove an adsorbate from the surface before driving the plasma supply unit; and
a reducing process by driving the plasma supply unit, after driving the hot plate, to supply the plasma to the surface that has undergone the degassing process.

2. The substrate processing device according to claim 1, further comprising:
a heat medium supply unit configured to supply a heat conductive gas to the chamber body, wherein the controller is configured to drive the heat medium supply unit to supply the heat conductive gas from the heat medium supply unit to the chamber body in the degassing process.

3. The substrate processing device according to claim 2, wherein the chamber body is connected to a discharge device by a main pipe, wherein the chamber body is also connected to the discharge device by a bypass pipe that bypasses the main pipe, wherein the bypass pipe has a flow passage resistance that is higher than that of the main pipe, and wherein the substrate processing device further comprises:
a main valve configured to open and close the main pipe; and
a bypass valve configured to open and close the bypass pipe, wherein
the controller is configured to:
open the main valve and close the bypass valve in the reducing process; and
close the main valve and open the bypass valve in the degassing process.

4. The substrate processing device according to claim 2, further comprising:
a support accommodated in the chamber body and configured to form a gap between the support and the hot plate and support the hot plate with a heat insulator arranged in the gap.

5. The substrate processing device according to claim 4, wherein the hot plate is connected to a power supply line for increasing a temperature of the hot plate, wherein an electric wire connected to the hot plate is only the power supply line, and wherein the controller is configured to increase a pressure of the chamber body in the degassing process to be higher than a pressure of the chamber body in the reducing process.

6. The substrate processing device according to claim 1, further comprising:
a diffusion member attached to the chamber body and formed from sintered alumina, the diffusion member being configured to diffuse the plasma supplied by the plasma supply unit into the chamber body, wherein the plasma supply unit includes:
a plasma generation unit configured to generate the plasma; and
a supply pipe attached to the chamber body and formed from sintered alumina, the supply pipe being configured to deliver the plasma generated by the plasma generation unit from the plasma generation unit toward the diffusion member.

7. A substrate processing system to reduce a surface of a substrate, the surface including a metal layer, the substrate processing system comprising:
a substrate processing device, the substrate processing device comprising:
a chamber body;
a hot plate located in the chamber body and configured to set the substrate;
a plasma supply unit configured to supply plasma of a hydrogen gas to the chamber body; and
a controller configured to execute:
a degassing process by driving the hot plate to remove an adsorbate from the surface before driving the plasma supply unit; and
a reducing process by driving the plasma supply unit, after driving the hot plate, to supply the plasma to the surface that has undergone the degassing process; and
a film forming chamber connected to the chamber body via a transfer chamber, wherein the metal layer is a first metal layer, and the film forming chamber is configured to form a second metal layer on the surface after the reducing process.

8. A method for processing a substrate that reduces a surface of the substrate, the surface including a metal layer, the method comprising:
a degassing process supplying a heat conductive gas to a chamber body, after setting the substrate on a hot plate accommodated in the chamber body, to increase a pressure of the chamber body and heating the hot plate to remove an adsorbate from the surface; and
a reducing process performed after discharging the heat conductive gas from the chamber body, the reducing process supplying plasma of a hydrogen gas to the surface of the substrate set on the hot plate that has undergone the degassing process.
